(19) United States
(12) Patent Application Publication
(10) Pub. No.: US 2024/0268191 A1
(43) Pub. Date: Aug. 8, 2024

(54) DISPLAY DEVICE

(71) Applicant: LG Display Co., Ltd., Seoul (KR)

(72) Inventors: Boeun JO, Paju-si (KR); MinJi KANG, Paju-si (KR)

(21) Appl. No.: 18/429,971

(22) Filed: Feb. 1, 2024

(30) Foreign Application Priority Data
Feb. 3, 2023 (KR) 10-2023-0014709

(51) Int. Cl. H10K 59/80; G06F 3/041; H10K 59/40

(52) U.S. Cl. CPC H10K 59/873; G06F 3/0412; H10K 59/40

(57) ABSTRACT

Embodiments of the disclosure relate to a display device and, more specifically, may provide an eco-friendly display device capable of process optimization, which may protect lines positioned in the non-display area from external moisture and oxygen by effectively encapsulating the lines as an end of the encapsulation layer includes a concave portion.

### CROSS-REFERENCE TO RELATED APPLICATION

This application claims priority from Korean Patent Application No. 10-2023-0014709, filed on Feb. 3, 2023, which is hereby incorporated by reference for all purposes as if fully set forth herein.

### BACKGROUND

### Technical Field

Embodiments of the disclosure relate to display devices.

### Description of Related Art

Recent display devices capable of displaying various information and interacting with users viewing the information are required to have various sizes, shapes, and functions.

These display devices include liquid crystal display (LCD) devices, electrophoretic display (FPD) devices, and light emitting diode (LED) display devices.

Light emitting diode display devices are self-emission display devices and, unlike liquid crystal display (LCD) devices, do not require a separate light source and may thus be manufactured in a lightweight and thin form. Further, light emitting diode display devices are not only advantageous in terms of power consumption due to low-voltage operation, but also have excellent color rendering, response speed, viewing angle, and contrast ratio (CR), and are being studied as next-generation display devices.

Display devices may provide a touch-based input method that allows users easier and more intuitive and convenient entry of information or commands without the need for buttons, a keyboard, a mouse, or other typical input means.

### BRIEF SUMMARY

The specification is directed to manufacturing aesthetic, lightweight, and thin display devices, which reduces the bezel area of the display area of the display device.

In implementing a lightweight, thin touch display device with a reduced bezel area, moisture and oxygen may penetrate into the bezel area, damaging the lines. When lines for implementing a plurality of light emitting elements and lines for providing a touch input method are positioned in the limited bezel area, the lines may not be sufficiently protected from external moisture and oxygen. Thus, the inventors of the disclosure have invented a display device capable of protecting lines positioned in the bezel area from external moisture and oxygen while providing a touch input method.

Embodiments of the disclosure may provide a display device having a thin bezel area while providing a touch input method and capable of effectively protecting lines positioned in the bezel area from external moisture and oxygen.

Embodiments of the disclosure may provide a display device comprising a display area where a plurality of subpixels are positioned, a non-display area positioned outside the display area, and an encapsulation layer extending from the display area to the non-display area, wherein an end of the encapsulation layer has a concave portion recessed toward the display area.

According to embodiments of the disclosure, there may be provided a display device capable of effectively protecting circuit lines positioned in the non-display area from external moisture and oxygen as an end of the encapsulation layer has a concave portion recessed toward the display area.

According to embodiments of the disclosure, there may be provided an eco-friendly display device capable of process optimization by enhancing durability by effectively encapsulating circuit lines and capable of preventing defects due to insufficient encapsulation of circuit lines positioned in the non-display area.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a cross-sectional view of a display device and a circuit diagram of a subpixel according to embodiments of the disclosure;

FIG. 3 is a view illustrating touch sensor patterns of a display device according to embodiments of the disclosure;

FIG. 4 is a plan view illustrating a display device according to embodiments of the disclosure;

FIG. 5 is a plan view illustrating a display device according to a comparative example;

FIG. 6 is a cross-sectional view taken along line A-A′ of FIG. 5;

FIG. 7 is a cross-sectional view taken along line B-B′ of FIG. 5.

FIG. 8 is a plan view illustrating a display device according to embodiments of the disclosure;

FIG. 9 is a cross-sectional view taken along line C-C′ of FIG. 8; and

FIG. 10 is a cross-sectional view taken along line D-D′ of FIG. 8.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

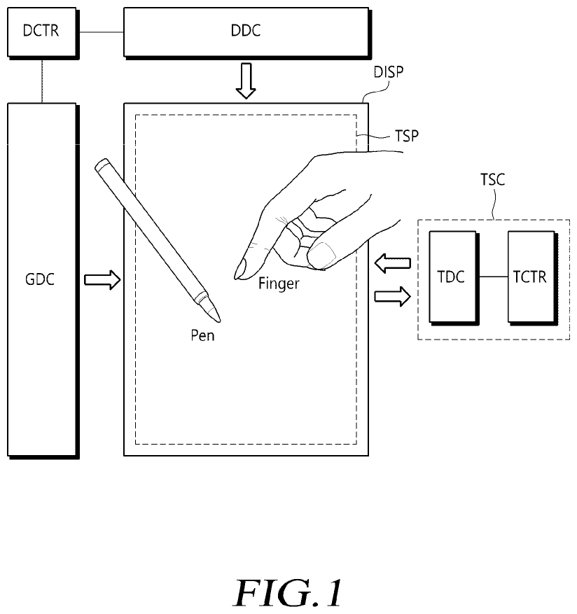

FIG. 1 is a view illustrating a system configuration of a display device according to embodiments of the disclosure.

Referring to FIG. 1, a display device according to embodiments of the disclosure may provide both an image display function for displaying an image and a touch sensing function for sensing the presence or absence of a touch and/or touch coordinates for a touch operation by a touch object such as the user's finger or pen.

To provide the image display function, the display device according to embodiments of the disclosure may include a display panel DISP, where a plurality of data lines and a plurality of gate lines are arranged, and a plurality of subpixels coupled to the plurality of data lines and the plurality of gate lines are arranged, a data driving circuit DDC for driving the plurality of data lines, a gate driving circuit GDC for driving the plurality of gate lines, and a display controller DCTR for controlling the data driving circuit DDC and the gate driving circuit GDC.

The data driving circuit DDC, the gate driving circuit GDC, and the display controller DCTR each may be implemented as one or more individual components. In some cases, two or more of the data driving circuit DDC, the gate driving circuit GDC, and the display controller DCTR may be integrated into a single component. For example, the data driving circuit DDC and the display controller DCTR may be implemented as a single integrated circuit (IC) chip.

To provide the touch sensing function, the display device according to embodiments of the disclosure may include a touch panel TSP including a touch sensor and a touch sensing circuit TSC supplying touch driving signals to the touch panel TSP, detecting touch sensing signals from the touch panel TSP, and sensing whether there is the user's touch or the position of a touch (touch coordinates) on the touch panel TSP based on the detected touch sensing signals.

For example, the touch sensing circuit TSC may include a touch driving circuit TDC supplying a touch driving signal to the touch panel TSP and detecting a touch sensing signal from the touch panel TSP and a touch controller TCTR sensing the presence or absence of the user's touch and/or the position of touch on the touch panel TSP based on the touch sensing signal detected by the touch driving circuit TDC.

The touch driving circuit TDC may include a first circuit part supplying a touch driving signal to the touch panel TSP and a second circuit part detecting a touch sensing signal from the touch panel TSP.

The touch driving circuit TDC and the touch controller TCTR may be implemented as separate components or, in some cases, may be integrated and implemented as one component.

Meanwhile, each of the data driving circuit DDC, gate driving circuit GDC and touch driving circuit TDC may be implemented as one or more integrated circuits and, in terms of electrical connection with the display panel DISP, be implemented in a chip-on-glass (COG) type, a chip-on-film (COF) type, or a tape carrier package (TCP) type. The gate driving circuit GDC may also be implemented in a gate-in-panel (GIP) type. Described below is an example in which the gate driving circuit GDC is implemented in the GIP type.

Meanwhile, each of the circuit components DDC, GDC, and DCTR for display driving and the circuit components TDC and TCTR for touch sensing may be implemented as one or more individual components. In some cases, one or more of the circuit components DDC, GDC, and DCTR for display driving and one or more of the circuit components TDC and TCTR for touch sensing may be functionally integrated and implemented as one or more components.

For example, the data driving circuit DDC and the touch driving circuit TDC may be implemented by being integrated into one or more integrated circuit chips. When the data driving circuit DDC and the touch driving circuit TDC are integrated into two or more integrated circuit chips, each of the two or more integrated circuit chips may have a data driving function and a touch driving function.

Meanwhile, display devices according to embodiments of the disclosure may be of various types, such as organic light emitting display devices and liquid crystal display devices. Described below is an example in which the display device and the display panel DISP are an organic light emitting display device and an organic light emitting display panel for convenience of description.

As is described below, the touch panel TSP may include a touch sensor capable of applying a touch driving signal or detecting a touch sensing signal, and may further include touch routing lines for electrically connecting the touch sensor and the touch driving circuit TDC.

The touch sensor may include touch electrode lines. Each touch electrode line may be of a bar type formed of one electrode or of a type in which multiple touch electrodes are connected. When each touch electrode line is of a type in which a plurality of touch electrodes are connected, each touch electrode line may include a plurality of touch electrodes and bridge pattern(s) connecting the plurality of touch electrodes. Such a touch sensor may include a touch sensor metal. Here, the touch sensor metal may include an electrode metal included in the touch electrode and a bridge metal included in the bridge pattern. The touch routing line may include at least one of the electrode metal and the bridge metal. In some cases, the touch sensor may be considered as further including touch routing lines as well as touch electrode lines.

The touch panel TSP may be present outside the display panel DISP. In other words, the touch panel TSP and the display panel DISP may be separately manufactured and then combined together. Such a touch panel TSP is referred to as an external type or an add-on type.

Unlike this, the touch panel TSP may be embedded in the display panel DISP. In other words, when manufacturing the display panel DISP, the touch sensor constituting the touch panel TSP may be formed together with electrodes and signal lines for display driving. Such a touch panel TSP is referred to as an embedded type. Hereinafter, for convenience of description, an example in which the touch panel TSP is an embedded type is described.

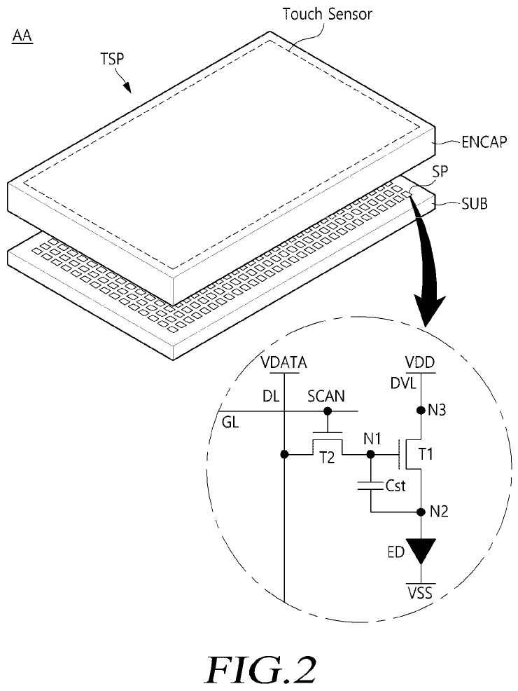

FIG. 2 is a cross-sectional view of a display device and a circuit diagram of a subpixel according to embodiments of the disclosure; More specifically, FIG. 2 is a view illustrating an example structure in which a touch panel is embedded in a display panel DISP according to an embodiment.

Referring to FIG. 2, in the display area AA of the display panel DISP, a plurality of subpixels SP may be disposed on the substrate SUB.

Each subpixel SP may include a light emitting element ED, a first transistor T1 for driving the light emitting element, a second transistor T2 for transferring a data voltage VDATA to a first node N1 of the first transistor T1, and a storage capacitor Cst for maintaining a constant voltage during one frame.

The first transistor T1 may include the first node N1 to which the data voltage may be applied, a second node N2 electrically connected with the light emitting element ED, and a third node N3 to which a driving voltage VDD is applied from a driving voltage line DVL. The first node N1 may be the gate node, the second node N2 may be the source node or the drain node, and the third node N3 may be the drain node or the source node. The first transistor T1 is referred to as a driving transistor for driving the light emitting element ED.

The light emitting element ED may include a pixel electrode (e.g., an anode electrode), a light emitting layer, and a common electrode (e.g., a cathode electrode). A data voltage VDATA corresponding to a different pixel voltage of each subpixel SP may be applied to the pixel electrode, and may be electrically connected to the second node N2 of the first transistor T1, and a base voltage VSS corresponding to a common voltage commonly applied to all subpixels SP may be applied to the common electrode.

The light emitting element ED may be a light emitting element ED using an organic material or a light emitting element ED using an inorganic material. In the light emitting element ED using an organic material, the light emitting layer may include an organic light emitting layer including an organic material. In this case, the light emitting element ED is referred to as an organic light emitting diode (OLED).

The second transistor T2 may be on/off controlled by a scan signal SCAN applied via the gate line GL and be electrically connected between the first node N1 of the first transistor T1 and the data line DL. The second transistor T2 is referred to as a switching transistor.

If the second transistor T2 is turned on by the scan signal SCAN, the data voltage VDATA supplied from the data line DL is transferred to the first node N1 of the first transistor T1.

The storage capacitor Cst may be electrically connected between the first node N1 and second node N2 of the first transistor T1.

Each subpixel SP may have a 2T (transistor) 1C (capacitor) structure which includes two transistors T1 and T2 and one capacitor Cst as shown in FIG. 2 and, in some cases, each subpixel SP may further include one or more transistors or one or more capacitors.

The storage capacitor Cst may be not the parasitic capacitor (e.g., Cgs or Cgd), the internal capacitor which may be present between the first node N1 and second node N2 of the first transistor T1, but an external capacitor intentionally designed outside the first transistor T1.

Each of the first transistor T1 and the second transistor T2 may be an n-type transistor or a p-type transistor.

As described above, circuit elements, such as the light emitting element ED, two or more transistors T1 and T2, and one or more capacitors Cst, are disposed on the display panel DISP. Since such circuit elements (particularly, the light emitting element ED) are vulnerable to external moisture or oxygen, an encapsulation layer ENCAP may be disposed on the display panel DISP to prevent penetration of external moisture or oxygen into the circuit elements (particularly, the light emitting element ED).

The encapsulation layer ENCAP may be formed of one or more layers. For example, when the encapsulation layer ENCAP is formed of a plurality of layers, the encapsulation layer ENCAP may include one or more inorganic encapsulation layers and one or more organic encapsulation layers. As a specific example, the encapsulation layer ENCAP may include a first inorganic encapsulation layer, an organic encapsulation layer, and a second inorganic encapsulation layer. Here, the organic encapsulation layer may be positioned between the first inorganic encapsulation layer and the second inorganic encapsulation layer.

The first inorganic encapsulation layer may be formed on the common electrode (e.g., the cathode electrode) to be closest to the light emitting element ED. For example, the first inorganic encapsulation layer may be formed of an inorganic insulation material capable of low-temperature deposition, such as, e.g., silicon nitride (SiNx), silicon oxide (SiOx), silicon oxynitride (SiON), or aluminum oxide (Al2O3). Accordingly, since the first inorganic encapsulation layer is deposited in a low-temperature atmosphere, it is possible to prevent the light emitting layer (organic light emitting layer) vulnerable to the high-temperature atmosphere from being damaged during the deposition process of the first inorganic encapsulation layer.

The organic encapsulation layer may be formed to have an area smaller than that of the first inorganic encapsulation layer, and may be formed to expose two opposite ends of the first inorganic encapsulation layer. The organic encapsulation layer serves as a buffer for relieving stress between layers due to bending of the display device and may also serve to enhance planarization performance. The organic encapsulation layer may be formed of, e.g., an acrylic resin, epoxy resin, polyimide, polyethylene, silicon oxycarbide (SiOC), or other organic insulation materials.

The second inorganic encapsulation layer may be formed on the organic encapsulation layer to cover the respective upper and side surfaces of the organic encapsulation layer and the first inorganic encapsulation layer. Thus, the second inorganic encapsulation layer may reduce or block penetration of external moisture or oxygen into the first inorganic encapsulation layer and the organic encapsulation layer. For example, the second inorganic encapsulation layer may include an inorganic insulating material, such as silicon nitride (SiNx), silicon oxide (SiOx), silicon oxynitride (SiON), or aluminum oxide (Al2O3).

In the display device according to embodiments of the disclosure, the touch panel TSP may be formed on the encapsulation layer ENCAP.

In other words, in the display device, a touch sensor included in the touch panel TSP may be disposed on the encapsulation layer ENCAP. This is called a touch sensor on encapsulation layer (TOE) structure.

During touch sensing, a touch signal (touch driving signal or touch sensing signal) may be applied to the touch sensor. Accordingly, during touch sensing, a potential difference due to the touch signal and the common voltage (base voltage VSS) may be formed between the touch sensor and the common electrode with the encapsulation layer ENCAP interposed therebetween, and accordingly, unnecessary parasitic capacitance may be formed from a touch sensing perspective. Since the parasitic capacitance may deteriorate touch sensitivity, the distance between the touch sensor and the common electrode may be designed to be a predetermined value (e.g., 5 μm) or more considering, e.g., panel thickness, panel manufacturing process, touch sensing performance, and display performance, so as to reduce the parasitic capacitance. The distance between the touch sensor and the common electrode is proportional to the thickness of the encapsulation layer ENCAP. Therefore, e.g., to reduce and prevent parasitic capacitance, the encapsulation layer ENCAP may be designed to have a thickness of at least 5 μm or more.

The display device according to embodiments of the disclosure may obtain the presence or absence of a touch and/or touch coordinates based on a change in self-capacitance using the touch sensor, or may obtain the presence or absence of a touch and/or touch coordinates based on a change in mutual-capacitance using the touch sensor. For convenience of description, an example in which the display device according to embodiments of the disclosure senses a touch based on mutual-capacitance is described below.

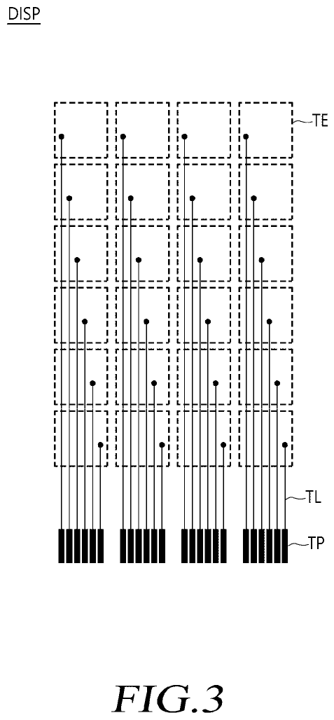

FIG. 3 is a view illustrating touch sensor patterns of a display panel DISP according to embodiments of the disclosure.

Referring to FIG. 3, touch sensor patterns (touch sensor metals) including a plurality of touch electrodes TE, a plurality of touch lines TL, and a plurality of touch pads TP may be disposed on a touch screen-embedded display panel DISP according to embodiments of the disclosure.

Since the plurality of touch electrodes TE are touch sensors for self-capacitance-based touch sensing, they simultaneously serve as driving electrodes and receiving electrodes (sensing electrodes).

Accordingly, the plurality of touch electrodes TE are electrically separated from each other.

Further, the plurality of touch electrodes TE do not overlap each other.

The plurality of touch lines TL are signal lines that electrically connect the plurality of touch electrodes TE and the touch sensing circuit TSC.

At the ends of the plurality of touch lines TL, there are a plurality of touch pads TP to which the touch sensing circuit TSC is electrically connected.

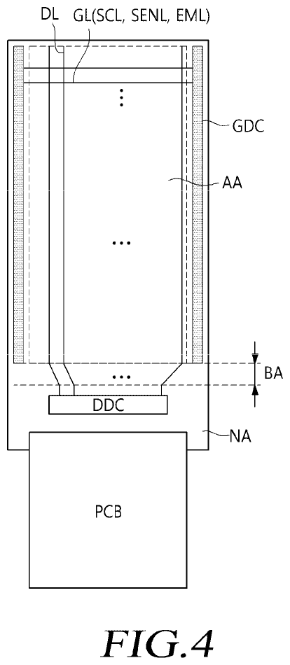

FIG. 4 is a plan view illustrating a display device according to embodiments of the disclosure.

Referring to FIG. 4, a display device according to embodiments of the disclosure may include a display area AA and a non-display area NA positioned outside the display area AA.

The display device may include a plurality of data lines DL, a plurality of gate lines GL, a data driving circuit DDC, and a gate driving circuit GDC.

The data driving circuit DDC may drive a plurality of data lines DL, and the gate driving circuit GDC may drive a plurality of gate lines GL. Also, although not shown, the display device may include a controller (not shown) for controlling the data driving circuit DDC and the gate driving circuit GDC. The controller may be implemented as a separate component from the data driving circuit DDC, or the controller CTR, along with the data driving circuit DDC, may be implemented as an integrated circuit.

The plurality of data lines DL and the plurality of gate lines GL may be disposed to cross each other. For example, the plurality of data lines DL may be arranged in rows or columns, and the plurality of gate lines GL may be arranged in columns or rows. For ease of description, it is assumed below that the plurality of data lines DL are arranged in rows, and the plurality of gate lines GL are arranged in columns.

The gate driving circuit GDC sequentially supplies scan signals of On voltage or Off voltage to the plurality of gate lines GL under the control of the controller.

When a specific gate line is opened by the gate driving circuit GDC, the data driving circuit DDC converts the image data received from the controller into an analog data voltage and supplies the analog data voltage to the plurality of data lines DL.

The plurality of gate lines GL disposed on the display panel PNL may include a plurality of scan lines SCL, a plurality of sense lines SCL, and a plurality of emission control lines EL. The scan line SCL, sense line SCL, and emission control line EL are lines for transferring different types of gate signals (scan signals, sense signals, and emission control signals) to the gate nodes of different types of transistors (scan transistors, sense transistors, and emission control transistors).

The gate driving circuit GDC and the data driving circuit DDC may be positioned in the non-display area NA. Further, a bending area BA may be positioned in the non-display area NA. The bending area BA may be positioned between the display area AA and the data driving circuit DDC. As the display device includes the bending area BA, the bending area BA may be bent to reduce the bezel area.

The display device may include a printed circuit board (PCB). The printed circuit board PCB may be a flexible printed circuit board (FPCB).

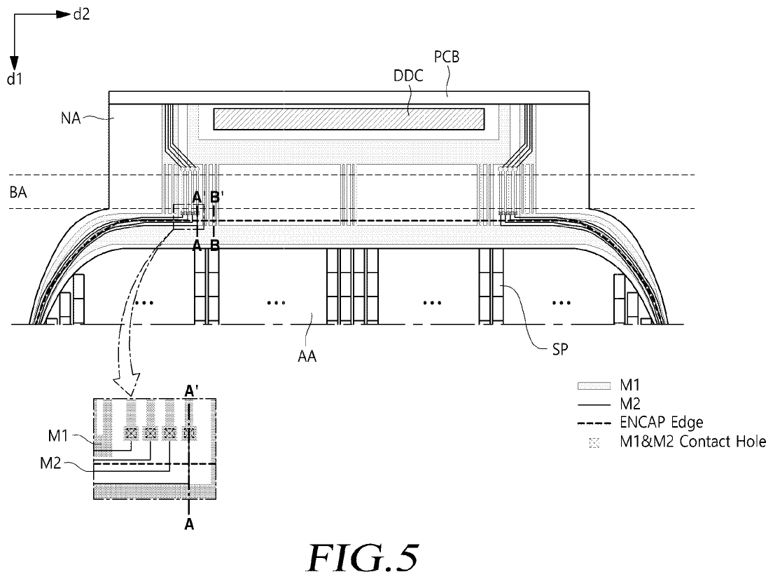

FIG. 5 is a plan view illustrating a display device according to an example. More specifically, FIG. 5 is a view illustrating a portion of a display area AA in which a plurality of subpixels SP are positioned and a portion of a non-display area NA.

Referring to FIG. 5, a plurality of subpixels SP may be positioned in the display area AA. The non-display area NA may be positioned outside the display area AA. The non-display area NA may include a bending area BA. The bending area BA may be positioned to extend in the second direction d2, which is the row direction of the display area AA, and may be positioned to be spaced apart from the display area AA by a predetermined distance in the first direction d1, which is the column direction. As the display device includes the bending area BA, a portion of the non-display area NA may be disposed toward the rear surface of the display device, thereby effectively reducing the size of the bezel area recognized by the user when the display device is used.

The display device may include an encapsulation layer (not shown) for encapsulating a plurality of subpixels SP. The encapsulation layer may be positioned throughout the display area AA to encapsulate the plurality of subpixels SP and may extend to the non-display area NA. In other words, the encapsulation layer may extend to an end (or edge portion) ENCAP Edge of the encapsulation layer positioned in the entire display area AA and the non-display area NA.

The encapsulation layer (not shown) may be a single layer or multiple layers. The display device may further include a dam (not shown) for supporting the encapsulation layer. The dam may be positioned closer to the display area AA than the end ENCAP Edge of the encapsulation layer. For example, the dam may be positioned adjacent to the display area AA by a predetermined distance from the end ENCAP Edge of the encapsulation layer, and may be positioned outside the display area AA. Further, the dam may be positioned surrounding the display area AA.

Lines for display driving and lines for touch driving may be positioned in the non-display area NA. These lines may include a first metal layer M1 and a second metal layer M2. The contact hole M1&M2 Contact Hole, to which the first metal layer M1 and the second metal layer M2 are electrically connected may be positioned further outside than the end ENCAP Edge of the encapsulation layer. In other words, the first metal layer M1 and the second metal layer M2 may be electrically connected to each other where the encapsulation layer is not positioned so that the first metal layer M1 and the second metal layer M2 may contact each other. The contact hole M1&M2 Contact Hole may be positioned between the display area AA and the bending area BA. As the contact hole M1&M2 Contact Hole is positioned between the display area AA and the bending area BA, and the first metal layer M1 and the second metal layer M2 are electrically connected in the contact hole M1&M2 Contact Hole, only the first metal layer M1 may be positioned in the bending area BA but the second metal layer M2 may not be positioned therein. The bending area BA is an area where bending of the display panel occurs, and when an excessive number of metal layers are positioned or a metal layer vulnerable to stress generated by bending is positioned, defects may occur in the product.

The encapsulation layer (not shown) may serve to protect not only the subpixel SP but also lines positioned in the non-display area from external moisture and oxygen. Lines positioned in an area closer to the display area AA than the end ENCAP Edge of the encapsulation layer may be protected by the encapsulation layer. For example, when the first metal layer M1 is positioned between the substrate (not shown) of the display device and the encapsulation layer (not shown), a portion of the first metal layer M1 that is closer to the display area AA than the end ENCAP Edge of the encapsulation layer may be protected from external moisture and oxygen by the encapsulation layer.

The thickness of the encapsulation layer may be important to effectively protect the lines under which the encapsulation layer is positioned. The inventors of the disclosure found that the positions of the end ENCAP Edge of the encapsulation layer, the dam (not shown), and the contact hole M1&M2 Contact Hole of the first metal layer and the second metal layer are critical factors to effectively protect a portion of the first metal layer M1, which is positioned closer to the display area AA than the end ENCAP Edge of the encapsulation layer by the encapsulation layer. This is why the thickness of the encapsulation layer covering the first metal layer M1 is varied depending on the distance between the end ENCAP Edge of the encapsulation layer and the dam (not shown) and the distance between the end ENCAP Edge of the encapsulation layer and the contact hole M1&M2 Contact Hole of the first metal layer and the second metal layer.

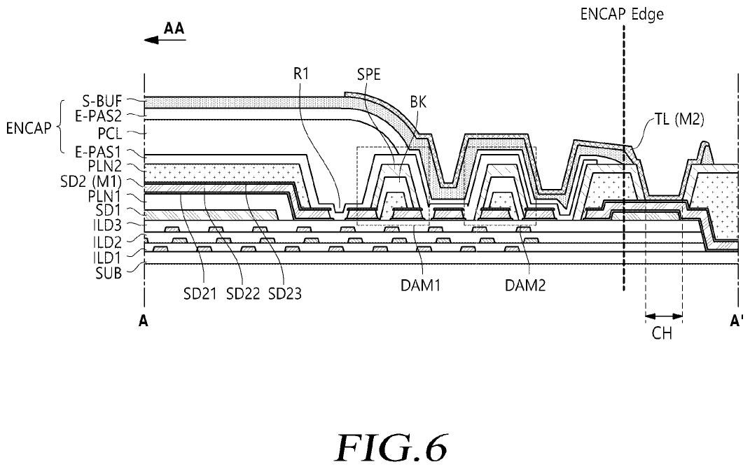

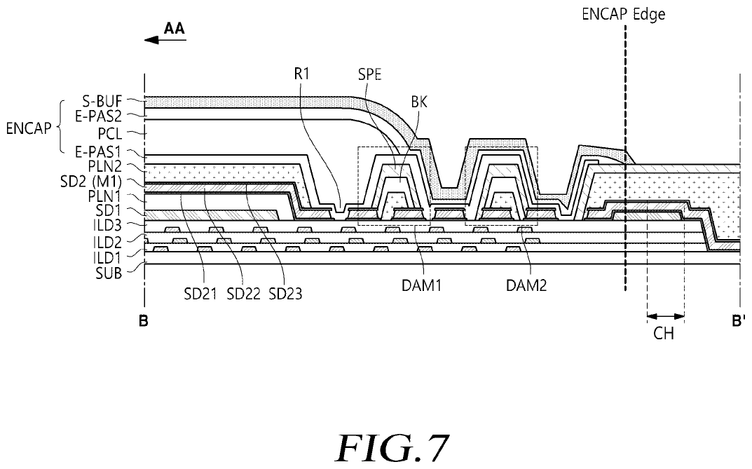

FIG. 6 is a cross-sectional view taken along line A-A′ of FIG. 5, and FIG. 7 is a cross-sectional view taken along line B-B′ of FIG. 5.

Referring to FIGS. 6 and 7, the display device may include a substrate SUB. The substrate SUB may be a single layer or multiple layers. The substrate SUB may be a glass substrate or a plastic substrate.

A plurality of insulation films and metal layers may be positioned on the substrate SUB. A transistor forming portion for driving a plurality of light emitting elements, a light emitting element forming portion in which the plurality of light emitting elements are positioned, and an encapsulation layer ENCAP for encapsulating the light emitting element may be sequentially positioned on the substrate SUB. The transistor forming portion may include various circuit elements and lines such as transistors and capacitors for driving the light emitting elements.

The interlayer insulation films ILD1, ILD2, and ILD3 and the planarization layers PLN1 and PLN2 may be positioned on the substrate SUB.

The first interlayer insulation film ILD1, the second interlayer insulation film ILD2, and the third interlayer insulation film ILD3 may be positioned. Metal layers constituting the transistor forming portion may be positioned on each of the interlayer insulation films ILD1, ILD2, and ILD3.

The first source-drain metal layer SD1 may be positioned on the third interlayer insulation film ILD3. The first source-drain metal layer SD1 may constitute the source-drain electrode of the transistor.

The first planarization layer PLN1 may be positioned on the first source-drain metal layer SD1. The first planarization layer PLN1 may be an organic insulation film.

The second source-drain metal layer SD2 may be positioned on the first planarization layer PLN2. The second source-drain metal layer SD2 may be the first metal layer M1 shown in FIG. 5. The second source-drain metal layer SD2 may constitute the source-drain electrode of the transistor.

The second source-drain metal layer SD2 may be a single layer or multiple layers. When the second source-drain metal layer SD2 includes multiple layers, the second source-drain metal layer SD2 may include a first layer SD21, a second layer SD22 positioned on the first layer SD21, and a third layer SD23 positioned on the second layer SD22. In this example, the first layer SD21 and the third layer SD23 may include titanium (Ti), and the second layer SD22 may include aluminum (Al).

The second planarization layer PLN2 may be positioned on the second source-drain metal layer SD2. The second planarization layer PLN2 may be an organic insulation film. In the display area AA, a plurality of light emitting elements may be positioned on the planarization layers PLN1 and PLN2. More specifically, a plurality of light emitting elements may be positioned on the second planarization layer PLN2.

The encapsulation layer ENCAP may be positioned on the planarization layers PLN1 and PLN2. More specifically, the encapsulation layer ENCAP may be positioned on the second planarization layer PLN2. The encapsulation layer ENCAP may be a single layer or multiple layers. FIGS. 6 and 7 illustrate examples in which the encapsulation layer includes multiple layers. The encapsulation layer ENCAP may include a first inorganic encapsulation layer E-PAS1, an organic encapsulation layer PCL positioned on the first inorganic encapsulation layer E-PAS1, and a second inorganic encapsulation layer E-PAS2 positioned on the organic encapsulation layer PCL.

The display device may include dams DAM1 and DAM2. The display device may include one or more dams, and may include, e.g., a first dam DAM1 and a second dam DAM2 positioned further outside than the first dam DAM1. The second dam DAM2 being positioned further outside than the first dam DAM1 may mean that the second dam DAM2 is positioned farther from the display area AA than the first dam DAM1.

The dams DAM1 and DAM2 may be composed of a plurality of layers. For example, the first dam DAM1 and the second dam DAM2 may include a second planarization layer PLN2, a bank BK positioned on the second planarization layer PLN2, and a spacer SPE positioned on the bank BK. In this example, the bank BK may be the same material layer as the bank defining the emission area of the subpixel in the display area AA. The spacer SPE may be the same material layer as the spacer positioned in the display area AA.

The dams DAM1 and DAM2 may serve to control the flow of the organic encapsulation layer PCL. Accordingly, the organic encapsulation layer PCL may not be positioned outside the first dam DAM1 or the second dam DAM2. Further, the planarization layers PLN1 and PLN2 may not be positioned outside the dams DAM1 and DAM2. Referring to FIGS. 6 and 7, the organic encapsulation layer PCL may not be positioned outside the first dam DAM1. Further, the planarization layers PLN1 and PLN2 may not be positioned in a partial area outside the first dam DAM1. Accordingly, in a partial area outside the first dam DAM1, there may be an area in which neither the organic encapsulation layer PCL nor the planarization layers PLN1 and PLN2 are stacked when viewed through the vertical cross section. When the second source-drain metal layer SD2 is positioned in such an area, a portion of the second source-drain metal layer SD2 may be exposed without being covered by the organic encapsulation layer PCL and the planarization layers PLN1 and PLN2. The organic encapsulation layer PCL and the planarization layers PLN1 and PLN2 are not positioned on the second source-drain metal layer SD2, but are substantially encapsulated only by the inorganic encapsulation layers E-PAS1 and E-PAS2. Therefore, in order for the second source-drain metal layers SD2 to be sufficiently encapsulated, it may be important that the inorganic encapsulation layers E-PAS1 and E-PAS2 have a sufficient thickness.

The above-described TOE structure may be positioned on the encapsulation layer ENCAP. The touch buffer layer S-BUF may be positioned on the encapsulation layer ENCAP. The touch line TL may be positioned on the touch buffer layer S-BUF. The touch line TL may be a second metal layer M2.

The end ENCAP Edge of the encapsulation layer may be positioned further outside than the second dam DAM2. The end ENCAP Edge of the encapsulation layer may be defined with respect to a layer extending longer outward of the display device among the inorganic encapsulation layers E-PAS1 and E-PAS2 constituting the encapsulation layer ENCAP.

In the display device according to the comparative example, the inventors of the disclosure found that the distance between the second dam DAM2 and the end ENCAP Edge of the encapsulation layer is related to the defect rate of the second source-drain metal layer SD2 which is the first metal layer M1.

In the outer portion of the first dam DAM1, an area in which only the inorganic encapsulation layers E-PAS1 and E-PAS2, which are thinner than the organic encapsulation layer PCL, are positioned on the second source-drain metal layer SD2 with respect to the vertical cross section may be positioned. In order to prevent defects due to external moisture and oxygen from occurring in the second source-drain metal layer SD2 in these areas, the second source-drain metal layer SD2 needs to be sufficiently covered by the thin inorganic encapsulation layers E-PAS1 and E-PAS2. However, when the second source-drain metal layer SD2 includes the first layer, the second layer, and the third layer described above, the second source-drain metal layer SD2 may have a shape in which the second layer is more eroded than the first layer and the third layer during the process. When the second source-drain metal layer SD2 has this shape, the first layer positioned on the relatively further eroded second layer may protrude further than the second layer. When the second layer has a further eroded shape and the first layer has a protruding shape, the step coverage of the thin inorganic encapsulation layers E-PAS1 and E-PAS2 may fall on the second source-drain metal layer SD2 and may not sufficiently cover the second source-drain metal layer SD2. The inventors of the disclosure have found that this problem occurs more frequently particularly when the distance between the end ENCAP Edge of the encapsulation layer and the second dam DAM2 is shorter.

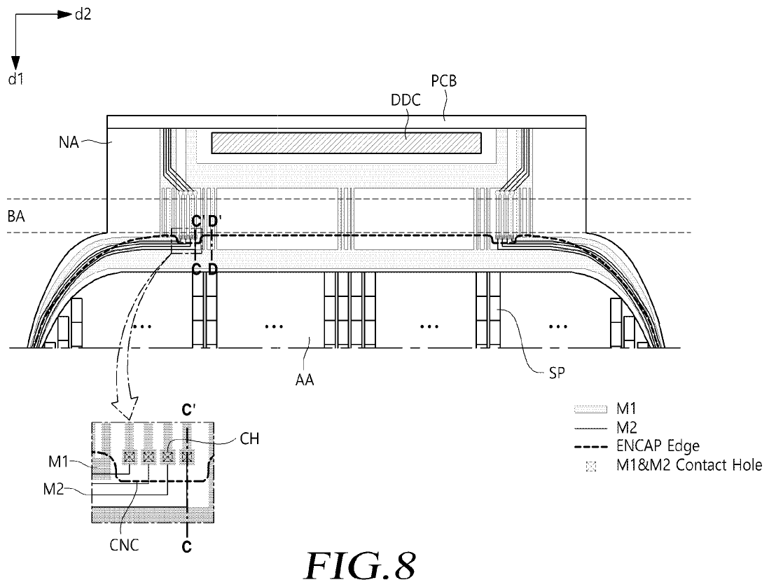

FIG. 8 is a plan view illustrating a display device according to embodiments of the disclosure. Unless otherwise described, same reference numerals or marks may be used to refer to the matters regarding the display device according to the embodiments illustrated in FIG. 8 and the matters of the display device described above with reference to FIG. 5, which does not limit the scope of the disclosure and does not mean that elements having a same reference numeral or marks are exactly the same.

Referring to FIG. 8, the display device may include a display area AA, a non-display area NA, and an encapsulation layer (not shown).

A plurality of subpixels SP may be positioned in the display area AA. The non-display area NA may be positioned outside the display area AA. In the non-display area NA, a data driving circuit DDC for driving a plurality of subpixels SP positioned in the display area AA and a plurality of lines may be positioned.

The encapsulation layer (not shown) may be positioned to extend from the display area AA to the non-display area NA. The encapsulation layer (not shown) may be positioned in the entire display area AA and may extend to the end (or edge portion) ENCAP Edge of the encapsulation layer.

The end ENCAP Edge of the encapsulation layer may include a concave portion CNC recessed toward the display area AA. As the end ENCAP Edge of the encapsulation layer includes the concave portion CNC recessed toward the display area AA, the lines positioned in the non-display area NA, e.g., the first metal layer M1, may be effectively encapsulated by the encapsulation layer, e.g., a portion of the encapsulation layer that does not include a concave portion, preventing defects in the display device.

The display device may include a contact hole CH. The contact hole CH may be positioned in the non-display area NA. Further, the contact hole CH may be positioned further outside than the end ENCAP Edge of the encapsulation layer. The contact hole CH being positioned further outside than the end ENCAP Edge of the encapsulation layer may mean that the contact hole CH is positioned farther from the display area AA than the end ENCAP Edge of the encapsulation layer. Further, it may mean that the contact hole CH does not penetrate the encapsulation layer. In some implementations, the contact hole CH is formed in the second planarization layer PLN2.

The concave portion CNC may be positioned corresponding to the contact hole CH. For example, the contact hole CH is aligned or overlap with the concave portion CNC in a direction d1 along which the concave portion recesses toward the display area. The encapsulation layer recedes away from the contact hole CH due to the concave portion CNC such that extra space is enabled or reserved for the formation of the contact hole CH without interfering with the encapsulation layer. The concave portion CNC being positioned corresponding to the contact hole CH may mean that the concave portion CNC is positioned so that the distance between the end ENCAP Edge of the encapsulation layer and the contact hole CH increases. Further, the concave portion CNC may be positioned adjacent to the contact hole CH. As the concave portion CNC is positioned corresponding to the contact hole CH, a margin required for the contact hole CH process may be secured because of the extra space enabled by the concave portion CNC.

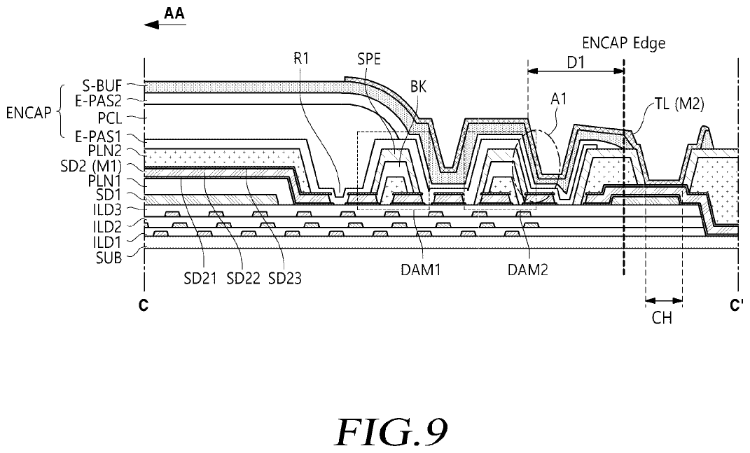

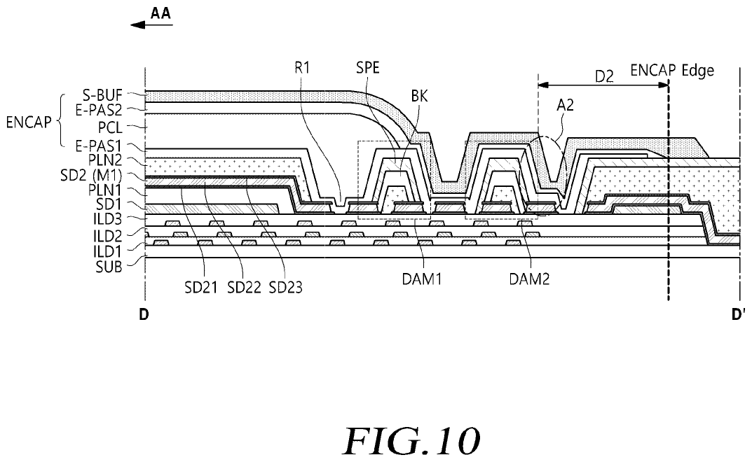

FIG. 9 is a cross-sectional view taken along line C-C′ of FIG. 8, and FIG. 10 is a cross-sectional view taken along line D-D′ of FIG. 8. More specifically, FIG. 9 is a cross-sectional view of a portion including the concave portion CNC of FIG. 8, and FIG. 10 is a cross-sectional view of a portion not including the concave portion CNC.

Referring to FIG. 9, the display device may include dams DAM1 and DAM2 positioned in the non-display area. The end ENCAP Edge of the encapsulation layer may be positioned further outside than the dam DAM1 or DAM2. In other words, the dams DAM1 and DAM2 may be positioned closer to the display area AA than the end ENCAP Edge of the encapsulation layer. Accordingly, the dams DAM1 and DAM2 may control the flow of the encapsulation layer ENCAP. In particular, the dams DAM1 and DAM2 may control the flow of the organic encapsulation layer PCL. In some implementations, one or more of the dams DAM1, DAM2 includes a same dielectric material as second planarization layer PLN2.

The display device may include a substrate SUB, a first metal layer M1 positioned on the substrate SUB, and a second metal layer M2 positioned on the encapsulation layer ENCAP. The first metal layer M1 may be a second source-drain metal layer SD2. The second metal layer M2 may be a touch line TL which is a touch sensor metal. In some implementations, the second metal layer M2 extend over one or more of the dams DAM1, DAM2 into the non-display area. The second metal layer M2 overlaps one or more of the dams DAM1, DAM2.

The first metal layer M1 and the second metal layer M2 may be electrically connected to each other in the contact hole CH. The second source-drain metal layer SD2 and the touch line TL may directly contact each other in the contact hole CH.

The second source-drain metal layer SD2, which is the first metal layer M1, may be a single layer or multiple layers. When the second source-drain metal layer SD2 includes multiple layers, the second source-drain metal layer SD2 may include a first layer SD21, a second layer SD22 positioned on the first layer, and a third layer SD23 positioned on the second layer. In this example, the first layer SD21 and the third layer SD23 may include titanium (Ti), and the second layer SD22 may include aluminum (Al). In this example, the second layer SD22 may have a shape further eroded than the first layer SD21 and the third layer SD23. For example, each of the first layer SD21 and the third layer SD23 protrudes further than the second layer SD22, and a recess portion R1 is formed among end portions of the first, second, and third layers SD21, SD22, SD23. In other words, the second source-drain metal layer SD2 of the display device illustrated in FIG. 9 may also have the encapsulation layer ENCAP coverage issues, like the second source-drain metal layer SD2 of the display device illustrated in FIGS. 6 and 7.

The concave portion of the encapsulation layer ENCAP corresponding to a first area A1 may be thinner than another portion of the encapsulation layer ENCAP corresponding to a second area A2. Referring to FIGS. 9 and 10, it may be identified that there is a difference in the sum of the thicknesses of the first inorganic encapsulation layer E-PAS1 and the second inorganic encapsulation layer E-PAS2 constituting the encapsulation layer ENCAP at the outer portion of the second dam DAM2. It is inferred that this difference comes from the fact that the distance D1 between the end ENCAP Edge of the encapsulation layer and the second dam DAM2 is relatively short in FIG. 9 (e.g., shorter than D2 in FIG. 10), which is the portion where the concave portion is positioned, and the distance D2 between the end ENCAP Edge of the encapsulation layer and the second dam DAM2 is relatively large in FIG. 10 (e.g., longer than D1 in FIG. 9), which is the portion where the concave portion is not positioned. Accordingly, according to embodiments of the disclosure, the end ENCAP Edge of the encapsulation layer of the remaining portion in which the concave portion is not positioned may secure a sufficient distance from the second dam DAM2, and the encapsulation layer ENCAP may be sufficiently thick between the dams DAM1 and DAM2 and the end ENCAP Edge of the encapsulation layer, thereby effectively preventing the first metal layer M1 from being damaged by external moisture and oxygen.

Embodiments of the disclosure described above are briefly described below.

A display device 100 according to embodiments of the disclosure may include a display area AA where a plurality of subpixels SP are positioned, a non-display area NA positioned outside the display area AA, and an encapsulation layer ENCAP extending from the display area AA to the non-display area NA. An end ENCAP Edge of the encapsulation layer may have a concave portion CNC recessed toward the display area AA.

The display device 100 may include a contact hole CH. The contact hole CH may be positioned in the non-display area NA and may be positioned further outside than the end ENCAP Edge of the encapsulation layer. The concave portion CNC may be positioned corresponding to the contact hole CH. The contact hole CH may be positioned further outside than the concave portion CNC.

The display device 100 may include a dam DAM1 or DAM2 positioned in the non-display area NA. The end ENCAP Edge of the encapsulation layer may be positioned further outside than the dam DAM1 or DAM2.

The display device 100 may include a substrate SUB, a first metal layer M1 positioned on the substrate SUB, and a second metal layer M2 positioned on the encapsulation layer ENCAP. The first metal layer M1 and the second metal layer M2 may be electrically connected to each other in the contact hole CH.

The display device 100 may include a touch sensor metal positioned on the encapsulation layer ENCAP. The second metal layer M2 may be a touch sensor metal.

The first metal layer M1 may include a first layer, a second layer positioned on the first layer, and a third layer positioned on the second layer. The second layer may have a shape further eroded than the first layer and the third layer.

The concave portion CNC of the encapsulation layer ENCAP may be thinner than another portion of the encapsulation layer ENCAP.

The display device 100 may include a planarization layer PLN1 or PLN2 positioned between the first metal layer M1 and the encapsulation layer ENCAP. A portion of the first metal layer M1 may be exposed without being covered by the planarization layer PLN1 or PLN2.

A distance between the end ENCAP Edge of the encapsulation layer and the dam DAM1 or DAM2 may be relatively short at a portion where the concave portion CNC is positioned.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed:

1. A display device, comprising:
a display area including a plurality of subpixels;
a non-display area positioned outside the display area; and
an encapsulation layer extending from the display area to the non-display area,
wherein an end of the encapsulation layer has a concave portion recessed toward the display area.

2. The display device of claim 1, further comprising a contact hole positioned in the non-display area and positioned farther from the display area than the end of the encapsulation layer,
wherein the concave portion is positioned corresponding to the contact hole.

3. The display device of claim 2, wherein the contact hole is positioned farther from the display area than the concave portion.

4. The display device of claim 1, further comprising a dam positioned in the non-display area,
wherein the end of the encapsulation layer is positioned farther from the display area than the dam.

5. The display device of claim 2, further comprising:
a substrate;
a first metal layer positioned on the substrate; and
a second metal layer positioned on the encapsulation layer,
wherein the first metal layer and the second metal layer are electrically connected to each other in the contact hole.

6. The display device of claim 5, wherein the second metal layer is configured as a touch sensor metal.

7. The display device of claim 5, wherein the first metal layer includes a first layer, a second layer positioned on the first layer, and a third layer positioned on the second layer, and
wherein the first layer and the third layer both protrude further than the second layer.

8. The display device of claim 1, wherein the concave portion of the encapsulation layer is thinner than another portion of the encapsulation layer.

9. The display device of claim 5, further comprising a planarization layer positioned between the first metal layer and the encapsulation layer,
wherein a portion of the first metal layer is not covered by the planarization layer.

10. The display device of claim 4, wherein a first distance between the dam and the concave portion of the end of the encapsulation layer is shorter than a second distance between the dam and another portion of the end of the encapsulation layer where the concave portion is not positioned.

11. A display device, comprising:
a substrate;
a first metal layer on the substrate;
an encapsulation layer on the first metal layer;
a second metal layer on the encapsulation layer; and
a contact hole through the encapsulation layer, with the first metal layer and the second metal layer being connected to each other through the contact hole,
wherein the encapsulation layer recedes away from the contact hole.

12. The display device of claim 11, comprising a dielectric layer between the encapsulation layer and the first metal layer, wherein the contact hole is in the dielectric layer.

13. The display device of claim 12, wherein the substrate includes a display area and a non-display area, and the contact hole is on the non-display area.

14. The display device of claim 13, comprising a dam in the non-display area and between the contact hole and the display area.

15. The display device of claim 14, wherein the dam and the dielectric includes a same dielectric material.

16. The display device of claim 14, wherein the second metal layer overlaps the dam.

17. The display device of claim 11, wherein the encapsulation layer includes a concave portion that recedes away from the contact hole.

18. The display device of claim 17, where the concave portion recesses toward the display area.

19. The display device of claim 11, wherein the second metal layer is configured as a touch sensor metal.

20. The display device of claim 11, wherein the first metal layer includes a first layer, a second layer positioned on the first layer, and a third layer positioned on the second layer, and
wherein the first layer and the third layer both protrude further than the second layer in a lateral direction.
